(19) United States
(12) Patent Application Publication
(10) Pub. No.: US 2011/0075879 A1
(43) Pub. Date: Mar. 31, 2011

(54) PIEZOELECTRIC MICRO SPEAKER WITH CURVED LEAD WIRES AND METHOD OF MANUFACTURING THE SAME

(75) Inventors: Dong-kyun KIM, Suwon-si (KR); Byung-gil JEONG, Anyang-si (KR); Seok-whan CHUNG, Suwon-si (KR); Jun-sik HWANG, Hwaseong-si (KR)

(73) Assignee: SAMSUNG ELECTRONICS CO., LTD., Suwon-si (KR)

(21) Appl. No.: 12/751,686

(22) Filed: Mar. 31, 2010

(30) Foreign Application Priority Data
Sep. 29, 2009 (KR) 10-2009-0092470

(51) Int. Cl. H04R 1/00; H01L 41/22; H04R 31/00

(52) U.S. Cl. 381/398; 29/25.35; 29/594

(57) ABSTRACT

A micro speaker includes a substrate having a cavity formed therein, a diaphragm formed on the substrate overlapping the cavity. The diaphragm includes a first vibration membrane formed in a first area corresponding to a center portion of the cavity and a second vibration membrane formed in a second area corresponding to an edge portion of the cavity and formed of material different from that used for the first vibration membrane. A piezoelectric actuator is formed including a first electrode layer formed on the first vibration membrane, a piezoelectric layer formed on the first electrode layer, and a second electrode layer formed on the piezoelectric layer, and first and second curved lead wires, respectively connected to the first and second electrode layers across the second area, which are symmetrical to the center of the piezoelectric actuator.

### CROSS-REFERENCE TO RELATED APPLICATIONS

This application claims priority from Korean Patent Application No. 10-2009-0092470, filed on Sep. 29, 2009, in the Korean Intellectual Property Office, the disclosures of which are incorporated herein in their entirety by reference.

### BACKGROUND OF THE INVENTION

1. Field

The present disclosure relates to a piezoelectric micro speaker, and more particularly, to a piezoelectric micro speaker with curved lead wires, and a method of manufacturing the same.

2. Description of the Related Art

Due to rapid development of terminals for personal voice communications and data communications, amounts of data to be transmitted and received has increased, while the terminals are required to be small and multifunctional.

In response to these trends, research into acoustic devices using micro electro mechanical system (MEMS) technology has been conducted. In particular, MEMS technology and semiconductor technology makes it possible to manufacture microspeakers with small size and low cost according to a package process and to easily integrate microspeakers with peripheral circuits.

Speakers using MEMS technology can be categorized into electrostatic-type speakers, electromagnetic-type speakers, and piezoelectric-type speakers. Piezoelectric micro speakers can be driven at lower voltages than electrostatic-type speakers, and have simpler and slimmer structures than electromagnetic-type speakers.

### SUMMARY

Provided is a piezoelectric micro speaker with curved lead wires and a method of manufacturing the same.

Additional aspects will be set forth in part in the description which follows and, in part, will be apparent from the description, or may be learned by practice of the presented embodiments.

According to one or more embodiments, a micro speaker includes a substrate having a cavity formed therein, a diaphragm formed on the substrate overlapping the cavity, the diaphragm including a first vibration membrane disposed in a first area corresponding to a center portion of the cavity and a second vibration membrane disposed in a second area corresponding to an edge portion of the cavity and formed of a material different from a material of the first vibration membrane, a piezoelectric actuator including a first electrode layer formed on the first vibration membrane, a piezoelectric layer formed on the first electrode layer, and a second electrode layer formed on the piezoelectric layer, and first and second lead wires respectively connected to the first and second electrode layers across the second area, wherein the first and second lead wires are curved and are symmetrical with respect to a center of the piezoelectric actuator.

First and second electrode pads may be provided on an upper surface of a second portion of the first vibration membrane located on the substrate and electrically connected to an external power. The first and second electrode pads may be arranged symmetrically with respect to the center of the piezoelectric actuator, the first lead wire may connect the first electrode pad and the first electrode layer across the second area, and the second lead wire may connect the second electrode pad and the second electrode layer across the second area.

The first lead wire may include a first end portion connected to the first electrode pad, a second end portion connected to the first electrode layer, and a curved portion connecting the first end portion and the second end portion. The second lead wire may include a first end portion connected to the second electrode pad, a second end portion connected to the second electrode layer, and a curved portion connecting the first end portion and the second end portion.

A first imaginary straight line may connect the first end portion of the first lead wire and the first end portion of the second lead wire; a second imaginary straight line may connect the second end portion of the first lead wire and the second end portion of the second lead wire, wherein the first imaginary straight line and the second imaginary straight line cross at a center of the piezoelectric actuator and form an angle θ₁.

A ratio of a diameter of the first portion of the first vibration membrane to a diameter of the cavity may be 70% to 90%, and the angle θ₁ may be between about 5° to 50°.

The ratio of the diameter of the first portion of the first vibration membrane to the diameter of the cavity may be 70% to 80%, and the angle θ₁ may be between about 20° to 50°.

The first end portion of the first lead wire and the first end portion of the second lead wire may extend in a straight line along the first imaginary straight line, and the second end portion of the first lead wire and the second end portion of the second lead wire may extend in a straight line along the second imaginary straight line.

The first end portions of the first and second lead wires may protrude a distance L_{b} into the second area; the second end portions of the first and second lead wires may protrude a distance Lₐ into the second area; and a width of each of the first and second lead wires may be W, where L_{b} is between about 1 W and 1.5 W and Lₐ is between about 1 W and 1.5 W.

The first vibration membrane may include support portions supporting the first and second lead wires and disposed in the second area, wherein the support portions may have the same shape as that of the first and second lead wires.

An elastic coefficient of a material of the second vibration membrane may be lower than an elastic coefficient of a material of the first vibration membrane.

The second vibration diaphragm may be formed of a polymer thin film.

The first vibration membrane may include a first portion disposed in the first area and a second portion disposed on the substrate, and the second vibration membrane may be disposed in the second area, on at least an edge portion of an upper surface of the piezoelectric actuator, and on an upper surface of the second portion of the first vibration membrane.

According to one or more embodiments, a method of manufacturing a micro speaker includes forming a first vibration membrane on a first surface of a substrate, forming a piezoelectric actuator by forming a first electrode layer on the first vibration membrane, forming a piezoelectric layer on the first electrode layer, and forming a second electrode layer on the piezoelectric layer, forming a trench in the first vibration membrane by etching the first vibration membrane, forming a second vibration membrane in the trench, wherein a material of the second vibration membrane is different from that of the first vibration membrane, and forming a cavity which penetrates the substrate by etching a second surface of the substrate, opposite the first surface, until the first and second vibration membranes are exposed, wherein the first vibration membrane comprises a first portion, inside the trench, which is disposed in a first area corresponding to a center portion of the cavity and the second vibration membrane is disposed in a second area corresponding to an edge portion of the cavity. The forming the piezoelectric actuator further comprises forming a first lead wire connected to the first electrode layer across the second area and forming a second lead wire connected to the second electrode layer across the second area, wherein the first lead wire and the second lead wire are curved and are symmetrical with respect to the center of the piezoelectric actuator.

In the forming of a piezoelectric actuator, a first electrode pad, connected to the first lead wire, and a second electrode pad connected to the second lead wire may be formed, and the first electrode pad and the second electrode pad may be symmetrical with respect to the center of the piezoelectric actuator.

The first lead wire may include a first end portion connected to the first electrode pad, a second end portion connected to the first electrode layer, and a curved portion connecting the first end portion and the second end portion. The second lead wire may include a first end portion connected to the second electrode pad, a second end portion connected to the second electrode layer, and a curved portion connecting the first end portion and the second end portion.

A first imaginary straight line may connect the first end portion of the first lead wire and the first end portion of the second lead wire, a second imaginary straight line may connect the second end portion of the first lead wire and the second end portion of the second lead wire, and the first imaginary straight line and the second imaginary straight line may cross at the center of the piezoelectric actuator and form an angle θ1 with each other.

A ratio of a diameter of the first portion of the first vibration membrane to a diameter of the cavity may be 70% to 80%, and the angle θ₁ may be between about 20° to 50°.

The first end portions of the first and second lead wires may extend in a straight line along the first imaginary straight line, and the second end portions of the first and second lead wires may extend in a straight line along the second imaginary straight line.

An elastic coefficient of the second vibration membrane may be lower than an elastic coefficient of the first vibration membrane.

The second vibration membrane may be disposed in the second area, on at least an edge portion of the upper surface of the piezoelectric actuator, and on an upper surface of the second portion of the first vibration membrane.

### BRIEF DESCRIPTION OF THE DRAWINGS

These and/or other aspects will become apparent and more readily appreciated from the following description of embodiments, taken in conjunction with the accompanying drawings of which:

FIG. 1 is a plan view illustrating a piezoelectric micro speaker according to an embodiment in which a second vibration membrane is not illustrated;

FIG. 2A is a cross-sectional view of the piezoelectric micro speaker taken along the line S1-S2 in FIG. 1;

FIG. 2B is a cross-sectional view of the piezoelectric micro speaker taken along the line S3-S4 in FIG. 1;

FIG. 3 is a plan view illustrating the shapes of the lead wires of FIG. 1 by magnifying the same;

FIG. 4A is a graph showing a result of simulation of a change in the minimum acoustic resonance frequency f1 according to the angle θ1 of FIG. 3, in the piezoelectric micro speaker of FIG. 1;

FIG. 4B is a graph showing a result of simulation of a change in the output sound pressure level at the frequency of 1 kHz according to the angle θ1 of FIG. 3, in the piezoelectric micro speaker of FIG. 1;

FIG. 4C is a graph showing a result of simulation of a change in the average output sound pressure level at a frequency between 1 kHz to 5 kHz according to the angle θ1 of FIG. 3, in the piezoelectric micro speaker of FIG. 1; and

FIGS. 5A-5E are cross-sectional views for explaining a method of manufacturing the piezoelectric micro speaker of FIG. 1.

### DETAILED DESCRIPTION

Reference will now be made in detail to embodiments, examples of which are illustrated in the accompanying drawings, wherein like reference numerals refer to the like elements throughout. In this regard, the present embodiments may have different forms and should not be construed as being limited to the descriptions set forth herein. Accordingly, the embodiments are merely described below, by referring to the figures, to explain aspects of the present description.

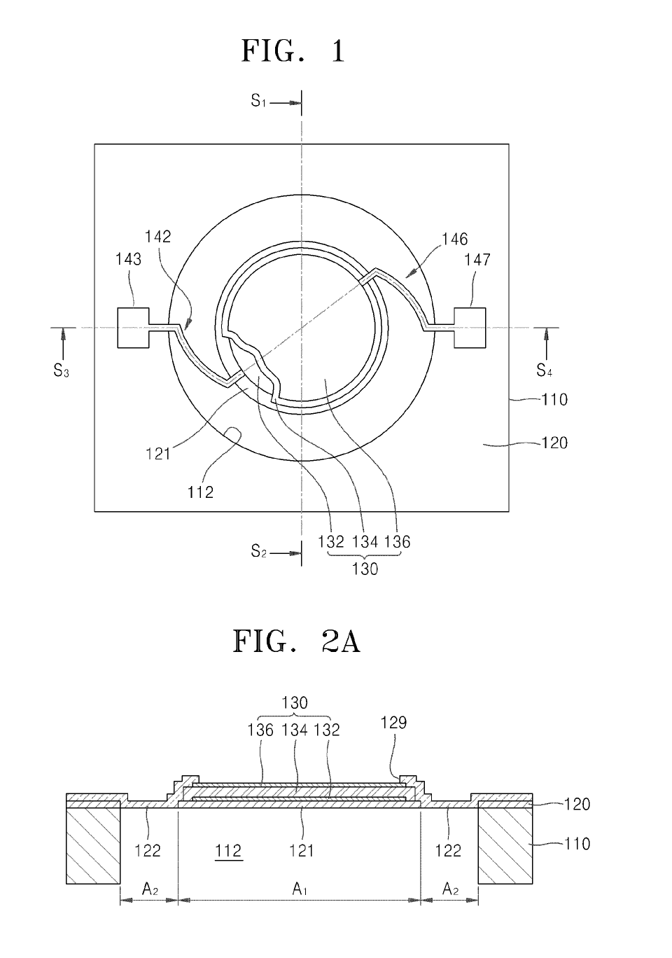

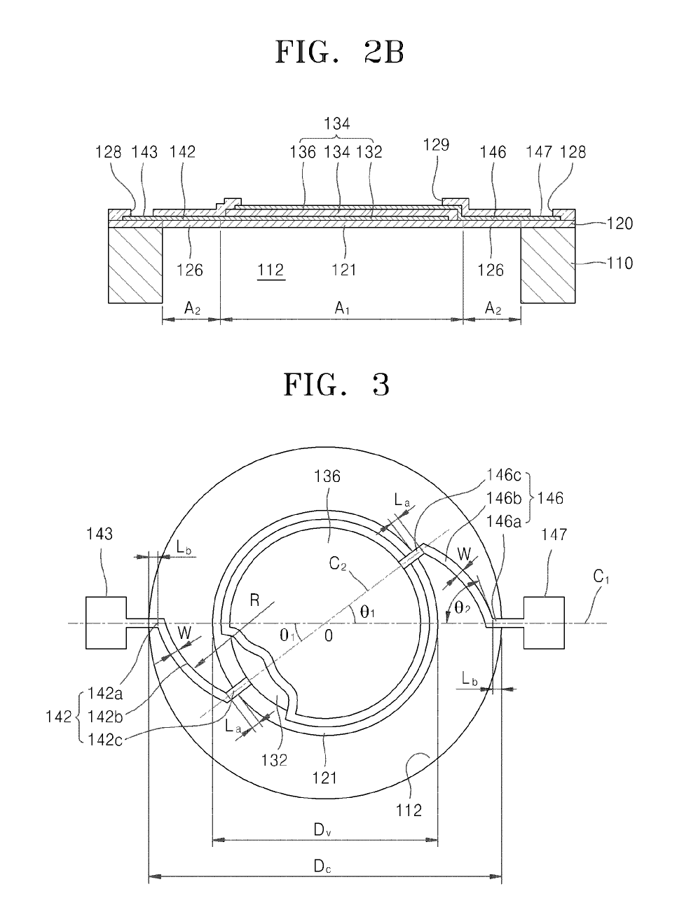

FIG. 1 is a plan view illustrating a piezoelectric micro speaker according to an embodiment in which a second vibration membrane is not illustrated. FIG. 2A is a cross-sectional view of the piezoelectric micro speaker taken along the lines S1-S2 in FIG. 1. FIG. 2B is a cross-sectional view of the piezoelectric micro speaker taken along the lines S3-S4 in FIG. 1.

Referring to FIGS. 1, 2A, and 2B together, a piezoelectric micro speaker according to the present embodiment includes a substrate 110 having a cavity 112, and a diaphragm 120 formed on the substrate 110 to cover the cavity 112. The diaphragm 120 includes first and second vibration membranes 121 and 122, and a piezoelectric actuator 130 is formed on the first vibration membrane 121. In detail, a silicon wafer that is easy to be finely processed may be used as the substrate 110. The cavity 112 may be formed in a predetermined area of the substrate 110 by penetrating the substrate 110 in the thickness direction thereof, for example, in a cylindrical shape.

The diaphragm 120 may be formed on a surface of the substrate 110 to have a predetermined thickness. The diaphragm 120 includes first and second vibration membranes 121 and 122 formed in an area corresponding to the cavity 112. The first vibration membrane 121 includes a first portion formed in a first area A₁ located over the center portion of the cavity 112, and a second portion formed on the surface of the substrate 110. The second vibration membrane 122 is formed in a second area A₂ located at the outer circumferential portion of the cavity 112. That is, the second vibration membrane 122 substantially radially surrounds the first portion of the first vibration membrane 121. The second vibration membrane 122 is arranged between the second portion of the first vibration membrane 121 and the first portion of the first vibration membrane 121, to connect the second portion of the first vibration membrane 121 and the first portion of the first vibration membrane 121, thereby supporting the first vibration membrane 121 and the piezoelectric actuator 130 formed thereon against the substrate 110.

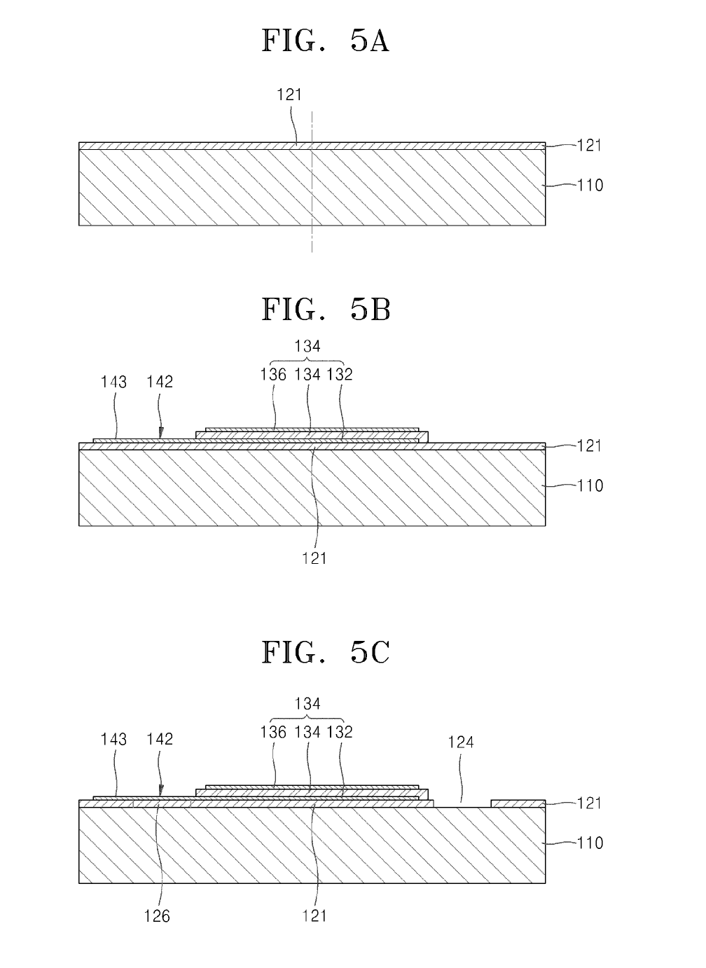

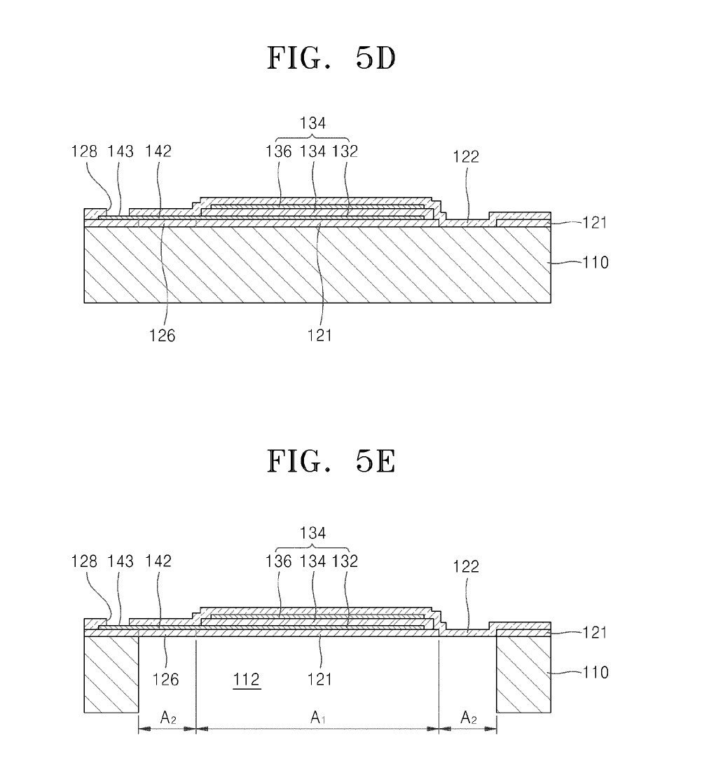

The second vibration membrane 122 may extend not only to the second area A₂ but also to the upper surface of the piezoelectric actuator 130 in the first area A₁ (inside the second area A₂) and to the upper surface of the second portion of the first vibration membrane 121, outside the second area A₂. In this case, one or more first apertures 128 expose a first electrode pad 143 and a second electrode pad 147, which are described later, to the outside. The second vibration membrane 122 may cover the upper surface of the piezoelectric actuator 130, or may cover only the edge portion of the upper surface of the piezoelectric actuator 130. To this end, a second aperture 129 to expose the upper surface of the second electrode layer 136 may be formed in the second vibration membrane 122. As illustrated in FIG. 5D, the second vibration membrane 122 may cover the entire upper surface of the piezoelectric actuator 130, thus covering the entire upper surface of the second electrode layer 136.

The first and second vibration membranes 121 and 122 may be formed of different materials. The second vibration membrane 122 may be formed of a soft material having a low elastic coefficient so as to be easily deformed compared to the first vibration membrane 121. The first vibration membrane 121 may be formed of material having an elastic coefficient of about 50 GPa to 500 GPa, for example, silicon nitride, while the second vibration membrane 122 may be formed of material having an elastic coefficient of about 100 MPa to 5 GPa, for example, a polymer thin film.

The piezoelectric actuator 130 may include a first electrode layer 132 disposed on the first portion of the first vibration membrane 121, a piezoelectric layer 134 disposed on the first electrode layer 132, and the second electrode layer 136 disposed on the piezoelectric layer 134. The first and second electrode layers 132 and 136 may be formed of a conductive metal material. The piezoelectric layer 134 may be formed of a piezoelectric material such as AN, ZnO, or PZT.

The first and second electrode pads 143 and 147 are electrically connected to an external power and are provided on the upper surface of the second portion of the first vibration membrane 121 located on the substrate 110. The first and second electrode pads 143 and 147 are arranged to be symmetrical with respect to the centers of the piezoelectric actuator 130 and the first vibration membrane 121. A first lead wire 142 is connected to the first electrode layer 132 of the piezoelectric actuator 130, while a second lead wire 146 is connected to the second electrode layer 136. That is, the first lead wire 142 connects the first electrode pad 143 and the first electrode layer 132 across the second area A₂, while the second lead wire 146 connects the second electrode pad 147 and the second electrode layer 136 across the second area A₂. The first and second lead wires 142 and 146 may be arranged at opposite sides so as to be symmetrical with respect to the centers of the piezoelectric actuator 130 and the first vibration membrane 121. The first and second lead wires 142 and 146 are formed to be curved, which will be described later in detail with reference to FIG. 3.

The first vibration membrane 121 may include a support portion 126 formed in the second area A₂ and supporting the first and second lead wires 142 and 146 may be. The support portion 126 may be formed of the same material as that of the first and second portions of the first vibration membrane 121 and may connect the first portion of the first vibration membrane 121 to the second portion of the first vibration membrane 121. As described above, although the second vibration membrane 122 connects the second portion of the first vibration membrane 121 and the first portion of the first vibration membrane 121, the support portion 126 may be disposed such that it only connects the second portion of the first vibration membrane 121 and the first portion of the first vibration membrane 121 in a region where the first and second lead wires 142 and 146 are disposed. The support portion 126 may have the same shape as that of the first and second lead wires 142 and 146.

FIG. 3 is a plan view illustrating the shapes of the lead wires of FIG. 1 by magnifying the same. Referring to FIG. 3, the first and second lead wires 142 and 146 are formed to be curved at the opposite sides of the piezoelectric actuator 130 and symmetrical with respect to a center O of the piezoelectric actuator 130. In detail, the first lead wire 142 may include a first end portion 142a connected to the first electrode pad 143, a second end portion 142c connected to the first electrode layer 132, and a curved portion 142b connecting between the first and second end portions 142a and 142c. Likewise, the second lead wire 146 may include a first end portion 146a connected to the second electrode pad 147, a second end portion 146c connected to the second electrode layer 136, and a curved portion 146b connecting between the first and second end portions 146a and 146c. The curved portions 142b and 146b are arranged in the second area A₂ and have a predetermined radius of curvature R.

The first end portions 142a and 146a are respectively connected to the first and second electrode pads 143 and 147 and may be arranged on a straight line C₁ that passes the center O and the first and second electrode pads 143 and 147. The second end portions 142c and 146c are respectively connected to outer circumferential portions of the first and second electrode layers 132 and 136 and may be arranged on a straight line C₂ that passes through the center O and is inclined by a predetermined angle θ₁ with respect to the straight line C₁. That is, the first end portion 142a and 146a and the center O are disposed along a first line C₁, the second end portions 142c and 146c are disposed along a second line C₂, and the first line C₁ and the second line C₂ cross at the center O of the piezoelectric actuator 130 and the first vibration membrane 121 and form an angle θ₁ with each other. Accordingly, the curved portions 142b and 146b connecting the first end portions 142a and 146a and the second end portions 142c and 146c have lengths extending through the angle θ₁. The radius of curvature R of the curved portions 142b and 146b may be greater than the radius of the first vibration membrane 121 and may vary according to the angle θ₁. An angle θ₂ is an angle between a tangent of the curved portions 142b and 146b at the end portions 142a and 146a with respect to the straight line C₁. The angle θ₂ may vary according to the angle θ₁. That is, as the angle θ₁ increases, the angle θ₂ increases accordingly.

The first end portions 142a and 146a and the second end portions 142c and 146c may be linear. This reduces the structural strength of the first vibration membrane 121 by decreasing the contact area between the first end portions 142a and 146a and the first and second electrode pads 143 and 147 and the contact area between the second end portions 142c and 146c and the first vibration membrane 121. In detail, the first end portions 142a and 146a may linearly extend along the straight line C₁ from each of the first and second electrode pads 143 and 147 to the second area A₂. That is, the first end portions 142a and 146a extend in a radial direction with respect to the cavity 112. The second end portions 142c and 146c may linearly extend along the straight line C₂ from each of the first and second electrode layers 132 and 136 to the second area A₂. That is, the second end portions 142c and 146c extend in a radial direction with respect to the outer circumference of the first vibration membrane 121. The first end portions 142a and 146a may have a length which extends a distance of L_{b} inside the second area A₂. The second end portions 142c and 146c may have a length which extends a distance of Lₐ inside the second area A₂. The width W of the first and second lead wires 142 and 146 may be about 30-70 μm. The lengths L_{b} and Lₐ of the first end portions 142a and 146a and the second end portions 142c and 146c protruding inside of the second area A₂ may be 1-1.5 times the width W.

If the first and second lead wires 142 and 146 were to extend straight along the straight line C₁ without any curved portion, the structural strength would increase relatively large enough to hinder vibrations of the first and second vibration membranes 121 and 122. That is, though the second vibration membrane 122 formed of a soft material is formed in the second area A₂, if the first and second lead wires 142 and 146 were straight lines crossing the second area A₂, they might hinder the vibrations of the first and second vibration membranes 121 and 122.

However, as illustrated in FIG. 3, when the first and second lead wires 142 and 146 are curved by extending through the angle θ₁ in the second area A₂, the structural strength may be substantially reduced as low as that of a case in which there is no lead wire.

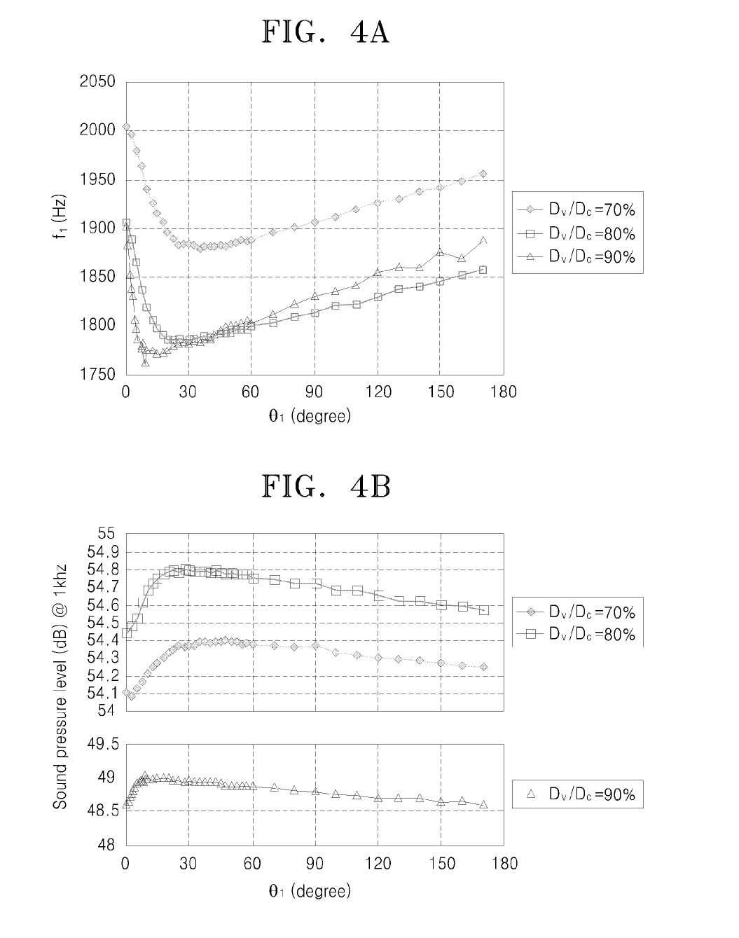

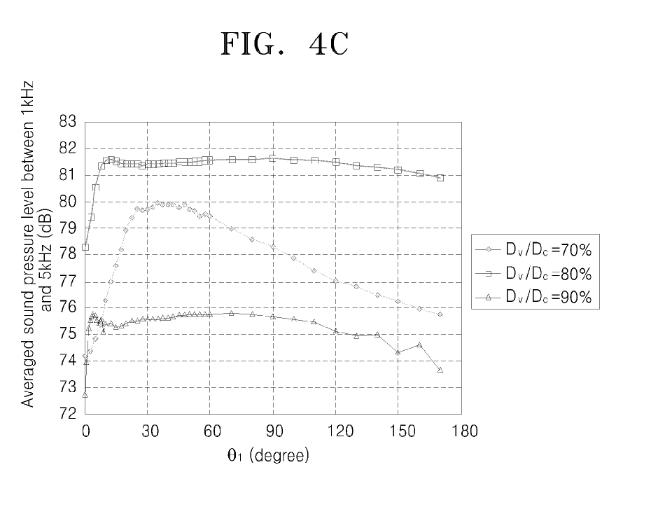

FIG. 4A is a graph showing a result of simulation of a change in the minimum acoustic resonance frequency f₁ according to the angle θ₁ of FIG. 3, in the piezoelectric micro speaker of FIG. 1. Referring to FIG. 4A, compared to a case in which the lead wires 142 and 146 are formed to be entirely linear (the angle θ₁ is 0° it can be seen that the minimum resonance frequency f₁ decreases when the lead wires 142 and 146 are formed to be curved (the angle θ₁ is greater than)0°. In detail, when a ratio D_{V}/D_{C} of the diameter D_{V} of the portion of the first vibration membrane 121 disposed over the cavity to the diameter D_{C} of the cavity 112 is 70%, the minimum resonance frequency f₁ is the lowest in a range in which the angle θ₁ is about 25° to 50°. When D_{V}/D_{C} is 80%, the minimum resonance frequency f₁ appears in a range in which the angle θ₁ is about 20° to 40°. When D_{V}/D_{C} is 90%, the minimum resonance frequency f₁ is the lowest in a range in which the angle θ₁ is about 5°-20°.

FIG. 4B is a graph showing a result of simulation of a change in the output sound pressure level at the frequency of 1 kHz according to the angle θ₁ of FIG. 3, in the piezoelectric micro speaker of FIG. 1. Referring to FIG. 4B, compared to a case in which the lead wires 142 and 146 are formed to be entirely linear (the angle θ₁ is 0° it can be seen that the output sound pressure level at the frequency of 1 kHz increases when the lead wires 142 and 146 are formed to be curved (the angle θ₁ is greater than)0°. In detail, when the ratio D_{V}/D_{C} of the diameter D_{V} of the portion of the first vibration membrane 121 disposed over the cavity to the diameter D_{C} of the cavity 112 is 70%, the highest output sound pressure level at the frequency of 1 kHz appears in a range in which the angle θ₁ is about 30° to 60°. When D_{V}/D_{C} is 80%, the highest output sound pressure level at the frequency of 1 kHz appears in a range in which the angle θ₁ is about 20° to 50°. When D_{V}/D_{C} is 90%, the highest output sound pressure level at the frequency of 1 kHz appears in a range in which the angle θ₁ is about 5° to 20°.

When D_{V}/D_{C} is 80%, the average output sound pressure level at the frequency of 1 kHz is relatively high. When D_{V}/D_{C} is 90%, the average output sound pressure level at the frequency of 1 kHz is relatively low.

FIG. 4C is a graph showing a result of simulation of a change in the average output sound pressure level at a frequency between 1 kHz to 5 kHz according to the angle θ₁ of FIG. 3, in the piezoelectric micro speaker of FIG. 1. Referring to FIG. 4C, compared to a case in which the lead wires 142 and 146 are formed to be linear (the angle θ₁ is 0° it can be seen that the average output sound pressure level at a frequency between 1 kHz to 5 kHz increases when the lead wires 142 and 146 are formed to be curved (the angle θ₁ is greater than 0°. In detail, when the ratio D_{V}/D_{C} of the diameter D_{V} of the portion of the first vibration membrane 121 disposed over the cavity to the diameter D_{C} of the cavity 112 is 70%, the highest average output sound pressure level at a frequency between 1 kHz to 5 kHz appears in a range in which the angle θ₁ is about 30°-50°. When D_{V}/D_{C} is 80%, the highest average output sound pressure level at a frequency between 1 kHz to 5 kHz appears in a range in which the angle θ₁ is not less than about 10°. When D_{V}/D_{C} is 90%, the highest average output sound pressure level at a frequency between 1 kHz to 5 kHz appears in a range in which the angle θ₁ is not less than about 5°.

When D_{V}/D_{C} is 80%, the average output sound pressure level at a frequency between 1 kHz to 5 kHz is relatively high. When D_{V}/D_{C} is 90%, the average output sound pressure level at a frequency between 1 kHz to 5 kHz is relatively low.

According to the above simulation results, when D_{V}/D_{C} is 70% to 90%, in a range in which the angle θ₁ is about 5° to 50°, it can be seen that the minimum resonance frequency f₁ decreases, the output sound pressure level at the frequency of 1 kHz increases, and the average output sound pressure level at a frequency between 1 kHz to 5 kHz increases. Also, it can be seen that the output sound pressure level is relatively high when D_{V}/D_{C} is 70% to 80%, compared to a case in which D_{V}/D_{C} is 90%.

Thus, when D_{V}/D_{C} is 70% to 80% and the angle θ₁ is about 20° to 50°, the minimum resonance frequency f₁ and the output sound pressure level are more effective.

As described above, in the embodiments of FIGS. 1-3, since the second vibration membrane 122 formed of a soft material having a relatively low elastic coefficient is arranged in the second area A₂ located at the edge portion of the cavity 112, the overall structural strength of the diaphragm 120 is lowered and thus the amount of deformation may be increased. Accordingly, the sound output may be improved.

Also, since the first and second lead wires 142 and 146 formed in the second area A₂ are formed to be curved, the structural strength is further lowered and thus a resonance frequency decreases. Accordingly, the output sound pressure level in the low frequency band may be improved and the average output sound pressure level at a frequency between 1 kHz to 5 kHz may be improved.

A method of manufacturing a piezoelectric micro speaker configured as above will be described below with reference to FIGS. 5A-5C. FIGS. 5A-5C are cross-sectional views for explaining a method of manufacturing the piezoelectric micro speaker of FIG. 1.

First, referring to FIG. 5A, the substrate 110 is prepared and a silicon wafer that is easy to be finely processed may be used therefor. The diaphragm 120 is formed on a surface of the substrate 110 to have a predetermined thickness. In detail, the first vibration membrane 121 may be formed by depositing an insulation material such as silicon nitride SiₓN_{y}, for example, Si₃N₄, on a surface of the substrate 110 with a thickness of 0.5 μm-3 μm by using a chemical vapor deposition (CVD) process. A portion of the first vibration membrane 121 formed in the first area A₁, located at the center portion of the cavity 112, functions as the portion of the first vibration membrane 121 which will be disposed over the cavity 112.

Next, as illustrated in FIG. 5B, the piezoelectric actuator 130 is formed on the first vibration membrane 121 of the diaphragm 120. The piezoelectric element 130 may be formed by depositing the first electrode layer 132 on the first vibration membrane, depositing the piezoelectric layer 134 on the first electrode layer, and depositing the second electrode layer 136 on the piezoelectric layer 134. In detail, the first electrode layer 132 may be formed by depositing conductive metal material, for example, Cr, Au, Mo, Cu, Al, Ti, or Pt, on the first vibration membrane 121 with a thickness of 0.1 μm-3 μm by using a sputtering or evaporation method, and then etching the same to be patterned into a predetermined shape. The first electrode layer 132 may be formed into a metal film of a single layer or multiple layers. The piezoelectric layer 134 may be formed by depositing piezoelectric material, for example, AlN, ZnO, PZT, PbTiO₃, or PLT, on the first electrode layer 134 with a thickness of 0.1 μm-3 μm by using a sputtering or spin-coating method. The piezoelectric layer 134 may be formed to be slightly larger than the first electrode layer 132 enough to cover the first electrode layer 132 so as to insulate the first electrode layer 132 from the second electrode layer 136. The second electrode layer 136 may be formed on the piezoelectric layer 134 in the same method as that used to form the first electrode layer 132.

Simultaneously with the formation of the first electrode layer 132, the first lead wire 142 connected to the first electrode layer 132 and the first electrode pad 143 connected to the end portion of the first lead wire 142 may be formed on the first vibration membrane 121. Also, simultaneously with the formation of the second electrode layer 136, the second lead wire 146 connected to the second electrode layer 136 and the second electrode pad 147 connected to the end portion of the second lead wire 146 may be formed on the first vibration membrane 121. The first and second lead wires 142 and 146 and the first and second electrode pads 143 and 147 may be formed by using the same material and method as those used for the first and second electrode layers 132 and 136. The first and second lead wires 142 and 146 are patterned to have the shape of FIG. 3.

Next, as illustrated in FIG. 5C, a trench 124 is formed in the second area A₂ located at the edge portion of the cavity 112 that is to be formed later in the operation of FIG. 5E, by etching the first vibration membrane 121. Then, the portion of the first vibration membrane 121 surrounded by the trench 124 is defined in the first area A₁ located at the center portion of the cavity 112. In the area of the second area A₂ where the first and second lead wires 142 and 146 are formed, the trench 124 is not be formed and the support portion 126 supporting the first and second lead wires 142 and 146 may remain instead. The support portion 126 remains directly under the first and second lead wires 142 and 146 and may have the same shape as that of the first and second lead wires 142 and 146.

Next, referring to FIG. 5D, the second vibration membrane 122 formed of material different from that used for the first vibration membrane 121 is formed in the trench 124. The second vibration membrane 122 may be formed of soft material having a low elastic coefficient, for example, a polymer thin film, so as to be easily deformed compared to the first vibration membrane 121. In detail, the first vibration membrane 121 may be formed of silicon nitride as described above, while the second vibration membrane 122 may be formed of parylene that is deposited with a thickness of, for example, 0.5 μm-10 μm.

The second vibration membrane 122 may extend not only to the second area A₂ but to the overall upper surface of the piezoelectric actuator 130 in the area A₁ (inside the second area A₂) and an upper surface of a second portion of the first vibration membrane 121 on the substrate 110 outside the second area A₂. The first aperture 128 to expose the first and second electrode pads 143 and 147 to the outside may be formed in the second vibration membrane 122 by partially etching the second vibration membrane 122 by using O₂ plasma. As illustrated in FIG. 2A, the second vibration membrane 122 may be formed to cover only the edge portion of the upper surface of the piezoelectric actuator 130. In this case, simultaneously with the formation of the first aperture 128, the second aperture 129 to expose the upper surface of the piezoelectric actuator 130, except for the edge portion thereof, may be formed in the second vibration membrane 122.

Next, as illustrated in FIG. 5E, the other surface of the substrate 110 is etched until the first and second vibration membranes 121 and 122 are exposed, thereby forming the cavity 112 penetrating the substrate 110 in the thickness direction thereof.

Accordingly, the first vibration membrane 121 is formed in the first area A₁ located at the center portion of the cavity 112. Also, a piezoelectric micro speaker having a structure is completed, in which the second vibration membrane 122 formed of the soft material and the first and second lead wires 142 and 146 that are curved are formed in the second area A₂ located at the edge portion of the cavity 112.

It should be understood that the embodiments described herein should be considered in a descriptive sense only and not for purposes of limitation. Descriptions of features or aspects within each embodiment should typically be considered as available for other similar features or aspects in other embodiments.

What is claimed is:

1. A micro speaker comprising:
a substrate having a cavity formed therein;
a diaphragm that is disposed on the substrate and overlaps the cavity, the diaphragm comprising:
a first vibration membrane disposed in a first area corresponding to a center portion of the cavity and a second vibration membrane disposed in a second area corresponding to an edge portion of the cavity, wherein a material of the second vibration membrane is different from a material of the first vibration membrane;
a piezoelectric actuator comprising a first electrode layer disposed on the first vibration membrane, a piezoelectric layer disposed on the first electrode layer, and a second electrode layer disposed on the piezoelectric layer;
a first lead wire that is disposed in the second area and is connected to the first electrode layer; and
a second lead wire that is disposed in the second area and is connected to the second electrode layer,
wherein the first and second lead wires are curved and are symmetrically disposed with respect to a center of the piezoelectric actuator.

2. The micro speaker of claim 1, wherein the first vibration membrane comprises a first portion disposed in the first area and a second portion disposed on the substrate, and
the micro speaker further comprising:
a first electrode pad which is disposed on an upper surface the second portion of the first vibration membrane and which is electrically connected to an external power, wherein the first lead wire connects the first electrode pad and the first electrode layer across the second area, and
a second electrode pad which is disposed on an upper surface of the second portion of the first vibration membrane and which is electrically connected to the external power, wherein the second lead wire connects the second electrode pad and the second electrode layer across the second area.

3. The micro speaker of claim 2, wherein:
the first lead wire comprises a first end portion connected to the first electrode pad, a second end portion connected to the first electrode layer, and a curved portion connecting the first end portion and the second end portion; and
the second lead wire comprises a first end portion connected to the second electrode pad, a second end portion connected to the second electrode layer, and a curved portion connecting the first end portion and the second end portion.

4. The micro speaker of claim 3, wherein:
a first imaginary straight line connects the first end portion of the first lead wire and the first end portion of the second lead wire;
a second imaginary straight line connects the second end portion of the first lead wire and the second end portion of the second lead wire; and
the first imaginary straight line and the second imaginary straight line cross at a center of the piezoelectric actuator and form an angle θ₁ with respect to each other.

5. The micro speaker of claim 4, wherein a ratio of a diameter of the first portion of the first vibration membrane to a diameter of the cavity is 70% to 90%, and the angle θ₁ is between about 5° to 50°.

6. The micro speaker of claim 5, wherein the ratio of the diameter of the first portion of the first vibration diaphragm to the diameter of the cavity is 70% to 80%, and the angle θ₁ is between about 20° to 50°.

7. The micro speaker of claim 4, wherein:
the first end portion of the first lead wire and the first end portion of the second lead wire each extend in a straight line along the first imaginary straight line, and
the second end portion of the first lead wire and the second end portion of the second lead wire each extend in a straight line along the second imaginary straight line.

8. The micro speaker of claim 7, wherein:
the first end portions of the first and second lead wires each protrude a distance L_{b} over the cavity;
the second end portions of the first and second lead wires each protrude a distance Lₐ over the cavity;
a width of each of the first and second lead wires is W;
L_{b} is between about 1 W and 1.5 W; and
Lₐ is between about 1 W and 1.5 W.

9. The micro speaker of claim 1, wherein the first vibration membrane further comprises support portions supporting the first and second lead wires and disposed in the second area, wherein the support portions have the same shape as that of the first and second lead wires.

10. The micro speaker of claim 1, wherein an elastic coefficient of the second vibration membrane is lower than an elastic coefficient of the first vibration membrane.

11. The micro speaker of claim 10, wherein the second vibration membrane is formed of a polymer thin film.

12. The micro speaker of claim 1, wherein
the first vibration membrane comprises a first portion disposed in the first area and a second portion disposed on the substrate; and
the second vibration membrane is disposed in the second area, at least an edge portion of an upper surface of the piezoelectric actuator, and an upper surface of the second portion of the first vibration membrane.

13. A method of manufacturing a micro speaker, the method comprising:
forming a first vibration membrane on a first surface of a substrate;
forming a piezoelectric actuator by forming a first electrode layer on the first vibration membrane, forming a piezoelectric layer on the first electrode layer, and forming a second electrode layer on the piezoelectric layer;
forming a trench in the first vibration membrane by etching the first vibration membrane;
forming a second vibration membrane in the trench, wherein a material of the second vibration membrane is different from a material of the first vibration membrane; and
forming a cavity which penetrates the substrate by etching a second surface of the substrate, opposite the first surface, until the first and second vibration membranes are exposed,
wherein the first vibration membrane comprises a first portion, inside the trench, which is disposed in a first area corresponding to a center portion of the cavity and the second vibration membrane is disposed in a second area corresponding to an edge portion of the cavity, and
wherein the forming the piezoelectric actuator further comprises:
forming a first lead wire, which is connected to the first electrode layer, across the second area, and
forming a second lead wire, which is connected to the second electrode layer, across the second area,
wherein the first lead wire is connected to the first electrode layer and is curved and the second lead wire is connected to the second electrode layer and is curved, and the first and second lead wires are symmetrically disposed with respect to a center of the piezoelectric actuator.

14. The method of claim 13, wherein the forming the piezoelectric actuator further comprises:
forming a first electrode pad connected to the first lead wire, and
forming a second electrode pad connected to the second lead wire,
wherein the first electrode pad and the second electrode pad are symmetrically disposed with respect to the center of the piezoelectric actuator.

15. The method of claim 14, wherein:
the first lead wire comprises a first end portion connected to the first electrode pad, a second end portion connected to the first electrode layer, and a curved portion connecting the first end portion and the second end portion, and
the second lead wire comprises a first end portion connected to the second electrode pad, a second end portion connected to the second electrode layer, and a curved portion connecting the first end portion and the second end portion.

16. The method of claim 15, wherein:
a first imaginary straight line connects the first end portion of the first lead wire and the first end portion of the second lead wire;
a second imaginary straight line connects the second end portion of the first lead wire and the second end portion of the second lead wire; and
the first imaginary straight line and the second imaginary straight line cross at the center of the piezoelectric actuator and form an angle θ₁ with respect each other.

17. The method of claim 16, wherein a ratio of a diameter of the first portion of the first vibration membrane to a diameter of the cavity is 70% to 80%, and the angle θ₁ is between about 20° to 50°.

18. The method of claim 15, wherein:
the first end portion of the first lead wire and the first end portion of the second lead wire each extend in a straight line along the first imaginary straight line, and
the second end portion of the first lead wire and the second end portion of the second lead wire each extend in a straight line along the second imaginary straight line.

19. The method of claim 13, wherein an elastic coefficient of the second vibration membrane is lower than an elastic coefficient of the first vibration membrane.

20. The method of claim 13, wherein:
the first vibration membrane further comprises a second portion disposed on the substrate outside the trench, and
the second vibration membrane is disposed in the second area, is disposed on at least an edge portion of an upper surface of the piezoelectric actuator, and is disposed on an upper surface of the second portion of the first vibration membrane.
